(19) United States
(12) Patent Application Publication
(10) Pub. No.: US 2023/0403893 A1
(43) Pub. Date: Dec. 14, 2023

(54) DISPLAY PANEL AND DISPLAY DEVICE

(71) Applicant: SHENZHEN CHINA STAR OPTOELECTRONICS SEMICONDUCTOR DISPLAY TECHNOLOGY CO., LTD., Guangdong (CN)

(72) Inventor: Jianxin Liu, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 17/431,147

(22) PCT Filed: Jul. 2, 2021
(86) PCT No.: PCT/CN2021/104217

§ 371 Date: Nov. 24, 2022

(30) Foreign Application Priority Data
May 17, 2021 (CN) 202110532574.3

(51) Int. Cl. H10K 59/131; H10K 59/88

(52) U.S. Cl. CPC H10K 59/131; H10K 59/88

(57) ABSTRACT

A display panel and a display device are disclosed. The display panel includes signal lines, and the signal lines include a signal main section disposed in a bezel area and a signal connecting section having one end connected to the signal main section and another end extending to a terminal area. The signal main section includes a first side and a second side, and the signal main section corresponding to the first side is adjacent to a display area. The signal connecting section includes a third side and a fourth side, the third side is connected to the first side, and at least a part of the signal connecting section corresponding to the third side is concavo-convex shaped.

### FIELD OF INVENTION

The present disclosure relates to the field of display technologies, and more particularly, to a display panel and a display device having the display panel.

### BACKGROUND OF INVENTION

Compared to liquid crystal displays (LCDs), organic light-emitting diode (OLED) displays have advantages such as high contrast, lightness and thinness, power saving, high saturation, and fast response times. At present, flagship mobile phone screens have widely used OLED screens, and high-end TV screens have also begun to use the OLED screens. However, the OLED screens are not perfect. Due to characteristics of organic materials of OLED devices, a service life thereof is easily attenuated, and OLED devices are also particularly sensitive to environments, especially to water vapor and oxygen. Therefore, during manufacturing processes of the OLED screens and subsequent uses thereof, special attention should be paid to a low water and oxygen environment of equipments when performing OLED evaporation or printing the OLED devices, as well as encapsulation abilities of the OLED screens for isolating water and oxygen. This is also directly related to reliability of the service life of the OLED screens.

At present, referring to FIGS. 1A and 1B, in a driving architecture design of the OLED devices, OLED display panels include a display area 1, a bezel area 2, and a terminal area 3. In order to realize display functions, transmitting electrical signals to the display area 1 is needed, so the terminal area 3 is provided with signal lines 4 for transmitting the electrical signals to the display area 1. In general, the signal lines 4 use a sandwich structure of Ti/Al/Ti, that is, the signal lines 4 include a first metal titanium layer 5, a metal aluminum layer 6, and a second metal titanium layer 7. During an etching process to form the signal lines 4, it is easy to cause the metal aluminum layer 6 positioned in a middle layer to be overly etched due to changes in compositions of etching solutions or fluctuations in process parameters such as temperatures. Therefore, side surfaces of the metal aluminum layer 6 will shrink relative to the first metal titanium layer 5 and the second metal titanium layer 7 after etching, thereby forming gaps 8. The gaps 8 still cannot be completely eliminated even if an insulating layer 9 is covered on the signal lines 4. Therefore, it is easy for water vapor to enter the gaps in the signal lines 4 and further enter the display area along arrow directions shown in FIG. 1A, thereby causing the OLED display panels to lose effectiveness or to have poor display.

Technical problem: an embodiment of the present disclosure provides a display panel and a display device to solve technical problems of display failure and poor display caused by metal wirings being prone to be over etched on sides and water vapor being prone to intrude the display area along the gaps formed by the sides of the metal wirings.

### SUMMARY OF INVENTION

In order to solve the above technical problems, an embodiment of the present disclosure provides a display panel. The display panel includes a display area, a bezel area adjacent to the display area, and a terminal area disposed on one side of the bezel area away from the display area.

The display panel further includes signal lines, and the signal lines include a signal main section disposed in the bezel area and a signal connecting section having one end connected to the signal main section in the bezel area and another end extending to the terminal area.

The signal main section includes a first side and a second side opposite to the first side, and the signal main section corresponding to the first side is adjacent to the display area.

The signal connecting section includes a third side and a fourth side opposite to the third side, the third side is connected to the first side, and at least a part of the signal connecting section corresponding to the third side is concavo-convex shaped.

In an embodiment of the present disclosure, the signal connecting section includes a first segment positioned in the bezel area and connected to the signal main section, and the first segment corresponding to the third side is concavo-convex shaped.

In an embodiment of the present disclosure, the signal connecting section further includes a second segment positioned in the terminal area and connected to the first segment, and the second segment corresponding to the third side is concavo-convex shaped.

In an embodiment of the present disclosure, a position in the signal connecting section being concavo-convex shaped is provided with a plurality of convex parts and a plurality of concave parts arranged alternatingly, and shape outlines of the convex parts and the concave parts are independently polygonal or arc-shaped.

In an embodiment of the present disclosure, the signal lines include a first signal line and a second signal line, the first signal line includes a first signal connecting section, the second signal line includes a second signal connecting section, and a position in the first signal connecting section being concavo-convex shaped is disposed opposite to a position in the second signal connecting section being concavo-convex shaped; and wherein, the convex parts on the first signal connecting section are disposed corresponding to the concave parts on the second signal connecting section by one to one, and shapes of the convex parts on the first signal connecting section match shapes of the concave parts on the second signal connecting section.

In an embodiment of the present disclosure, the signal connecting section corresponding to the fourth side is concavo-convex shaped.

In an embodiment of the present disclosure, the convex parts of the signal connecting section corresponding to the third side are staggered from the concave parts of the signal connecting section corresponding to the fourth side.

In an embodiment of the present disclosure, the convex parts of the signal connecting section corresponding to the third side correspond to the concave parts of the signal connecting section corresponding to the fourth side by one to one.

In an embodiment of the present disclosure, the signal main section corresponding to the first side is concavo-convex shaped.

Based on the above objectives of the present disclosure, a display device is provided. The display device includes a display panel, which includes a display area, a bezel area adjacent to the display area, and a terminal area disposed on one side of the bezel area away from the display area.

The display panel further includes signal lines, and the signal lines include a signal main section disposed in the bezel area and a signal connecting section having one end connected to the signal main section in the bezel area and another end extending to the terminal area.

The signal main section includes a first side and a second side opposite to the first side, and the signal main section corresponding to the first side is adjacent to the display area.

The signal connecting section includes a third side and a fourth side opposite to the third side, the third side is connected to the first side, and at least a part of the signal connecting section corresponding to the third side is concavo-convex shaped.

In an embodiment of the present disclosure, the signal connecting section includes a first segment positioned in the bezel area and connected to the signal main section, and the first segment corresponding to the third side is concavo-convex shaped.

In an embodiment of the present disclosure, the signal connecting section further includes a second segment positioned in the terminal area and connected to the first segment, and the second segment corresponding to the third side is concavo-convex shaped.

In an embodiment of the present disclosure, a position in the signal connecting section being concavo-convex shaped is provided with a plurality of convex parts and a plurality of concave parts arranged alternatingly, and shape outlines of the convex parts and the concave parts are independently polygonal or arc-shaped.

In an embodiment of the present disclosure, the signal lines include a first signal line and a second signal line, the first signal line includes a first signal connecting section, the second signal line includes a second signal connecting section, and a position in the first signal connecting section being concavo-convex shaped is disposed opposite to a position in the second signal connecting section being concavo-convex shaped; and wherein, the convex parts on the first signal connecting section are disposed corresponding to the concave parts on the second signal connecting section by one to one, and shapes of the convex parts on the first signal connecting section match shapes of the concave parts on the second signal connecting section.

In an embodiment of the present disclosure, the signal connecting section corresponding to the fourth side is concavo-convex shaped.

In an embodiment of the present disclosure, the convex parts of the signal connecting section corresponding to the third side are staggered from the concave parts of the signal connecting section corresponding to the fourth side.

In an embodiment of the present disclosure, the convex parts of the signal connecting section corresponding to the third side correspond to the concave parts of the signal connecting section corresponding to the fourth side by one to one.

In an embodiment of the present disclosure, the signal main section corresponding to the first side is concavo-convex shaped.

Beneficial effect: compared to current technology, the signal lines provided by the present disclosure include the signal main section disposed in the bezel area and the signal connecting section having one end connected to the signal main section in the bezel area and another end extending to the terminal area. The signal main section includes the first side and the second side opposite to each other, and the signal connecting section includes the third side and the fourth side opposite to each other. Wherein, the signal main section corresponding to the first side is adjacent to the display area, the first side is connected to the third side, and at least the part of the signal connecting section corresponding to the third side is concavo-convex shaped. That is, by setting sides of the signal connecting section to be concavo-convex shaped on an intruding path of water vapor, the present disclosure, in one aspect, can extend the intruding path of the water vapor, and in another aspect, since undulations of the sides are bent or curved and the signal lines are not prone to be over etched on the sides being bent or curved, the intruding path of the water vapor can be blocked. Therefore, the present disclosure can effectively reduce a probability of the water vapor entering the display area from gaps formed on the sides of the signal lines, thereby reducing a phenomenon of the display panel losing effectiveness or having poor display due to intrusion by the water vapor, and improving yields of the display panel.

### DESCRIPTION OF DRAWINGS

The following detailed description of specific embodiments of the present disclosure will make the technical solutions and other beneficial effects of the present disclosure obvious with reference to the accompanying drawings.

FIG. 1A is a schematic structural diagram of a distribution of signal lines in current technology.

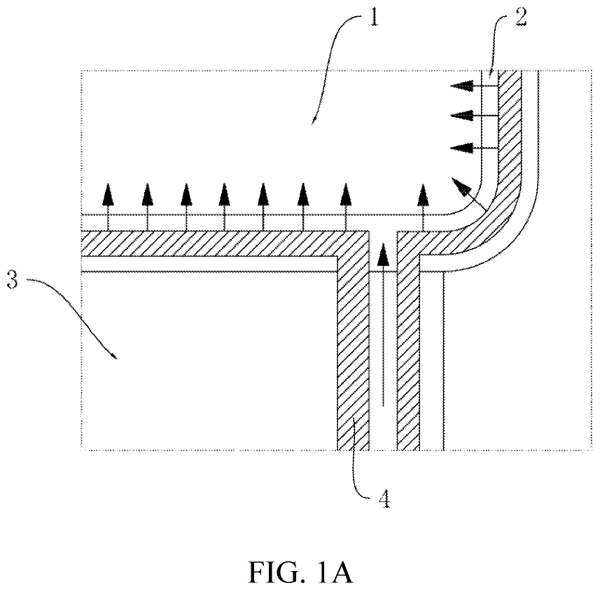

FIG. 1B is a schematic structural diagram of the signal lines in a display panel in current technology.

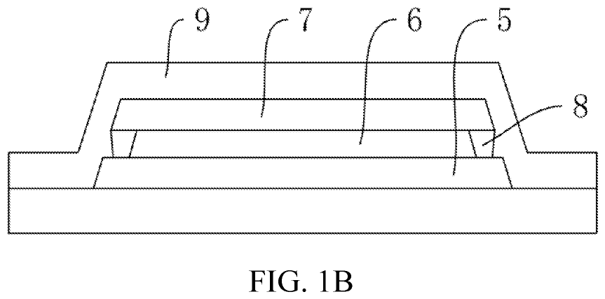

FIG. 2 is a schematic planar structural distribution diagram of a display panel according to an embodiment of the present disclosure.

FIG. 3 is a schematic structural distribution diagram of signal lines in the display panel according to an embodiment of the present disclosure.

FIG. 4 is another schematic structural distribution diagram of the signal lines in the display panel according to an embodiment of the present disclosure.

FIG. 5 is yet another schematic structural distribution diagram of the signal lines in the display panel according to an embodiment of the present disclosure.

FIG. 6 is still another schematic structural distribution diagram of the signal lines in the display panel according to an embodiment of the present disclosure.

FIG. 7 is still another schematic structural distribution diagram of the signal lines in the display panel according to an embodiment of the present disclosure.

FIG. 8 is still another schematic structural distribution diagram of the signal lines in the display panel according to an embodiment of the present disclosure.

FIG. 9 is still another schematic structural distribution diagram of the signal lines in the display panel according to an embodiment of the present disclosure.

FIG. 10 is a schematic structural diagram of a signal connecting section of the signal lines according to an embodiment of the present disclosure.

### DETAILED DESCRIPTION OF PREFERRED EMBODIMENTS

The technical solutions in the embodiments of the present disclosure will be clearly and completely described below with reference to the drawings in the embodiments of the present disclosure. Obviously, the described embodiments are only a part of the embodiments of the present disclosure, but not all the embodiments. Based on the embodiments in the present disclosure, all other embodiments obtained by those skilled in the art without creative efforts are within the scope of the present disclosure.

In the description of the present disclosure, it can be understood that terms such as “first” and “second” are used herein for purposes of description and are not intended to indicate or imply relative importance or implicitly indicating the number of technical features indicated. Thus, features limited by “first” and “second” are intended to indicate or imply including one or more than one these features. In the description of the present disclosure, “a plurality of” relates to two or more than two, unless otherwise specified.

The following description provides many different embodiments or examples for implementing different structures of the present disclosure. In order to simplify the present disclosure, the components and settings of a specific example are described below. Of course, they are merely examples and are not intended to limit the present disclosure. In addition, the present disclosure may repeat reference numerals and/or reference letters in different examples, which are for the purpose of simplicity and clarity, and do not indicate the relationship between the various embodiments and/or arrangements discussed. In addition, the present disclosure provides examples of various specific processes and materials, but one of ordinary skill in the art will recognize the use of other processes and/or the use of other materials.

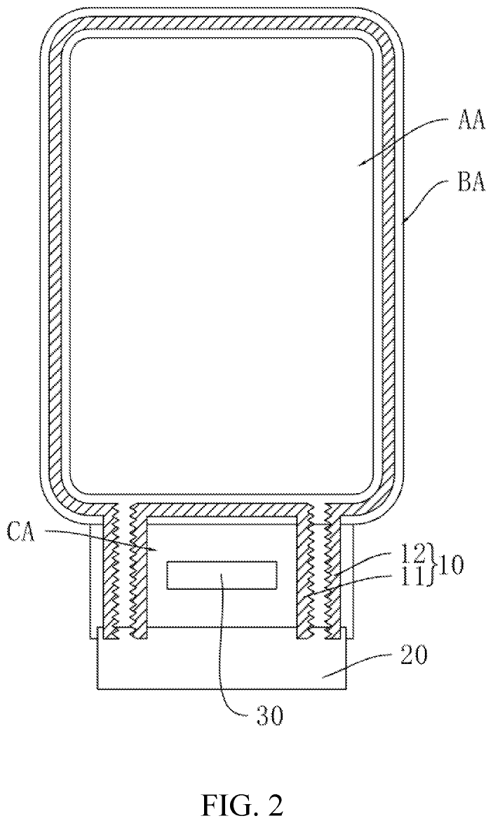

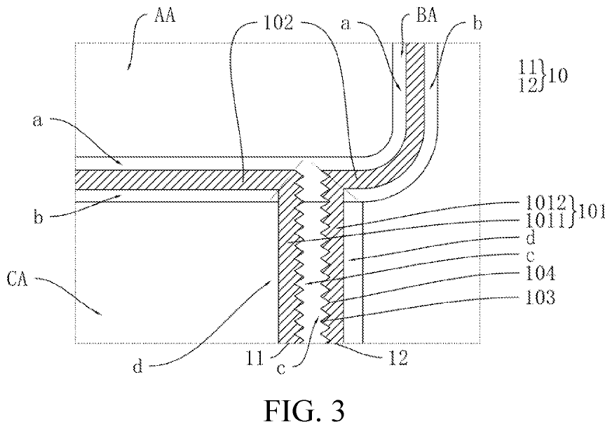

Referring to FIGS. 2 and 3, an embodiment of the present disclosure provides a display panel, which includes a display area AA, a bezel area BA adjacent to the display area AA, and a terminal area CA disposed on one side of the bezel area BA away from the display area AA. Specifically, the bezel area BA surrounds the display area AA, the terminal area CA is disposed on one side of the display area AA, and the bezel area BA is between the terminal area CA and the display area AA.

Corresponding to the display area AA, the display panel is provided with a thin film transistor array layer, an organic light-emitting functional layer, and an encapsulation layer. In-plane wirings and electrode components are disposed corresponding to the bezel area BA, wherein, the in-plane wirings are electrically connected to transistor devices in the thin film transistor array layer, and the electrode components are disposed in the organic light-emitting functional layer and extend to the bezel area BA. Optionally, the electrode components may be a surface cathode layer, and is not limited here. The structures mentioned above are not shown in the figures and can be manufactured according to conventional processes, and are not repeated here.

The display panel further includes signal lines 10, a flexible circuit board 20, and a driving chip 30. One end of the flexible circuit board 20 is connected to one side of the terminal area CA away from the display area AA, and the driving chip 30 is bonded in the terminal area CA of the display panel. Wherein, the driving chip 30 is configured to control generation and transmission of electrical signals, and the signal lines 10 are connected to the flexible circuit board 20 and extend to the bezel area BA to be connected to the in-plane wirings and the electrode components in the bezel area BA, thereby transmitting the electrical signals to the display area AA for realizing display functions.

In the embodiment of the present disclosure, the signal lines 10 include a signal main section 102 disposed in the bezel area BA and a signal connecting section 101 having one end connected to the signal main section 102 in the bezel area BA and another end extending to the terminal area CA. The signal main section 102 includes a first side a and a second side b opposite to the first side a, and the signal main section 102 corresponding to the first side a is adjacent to the display area AA.

The signal connecting section 101 includes a third side c and a fourth side d that are opposite to each other, the third side c is connected to the first side a, and at least a part of the signal connecting section 101 corresponding to the third side c is concavo-convex shaped.

In implementation processes, water vapor is prone to intrude the display area AA from the third side c of the signal connecting section 101 and the first side a of the signal main section 102. By setting at least the part of the signal connecting section 101 corresponding to the third side c to be concavo-convex shaped, the present disclosure, in one aspect, can extend an intruding path of the water vapor, and in another aspect, since a position on the third side c being concavo-convex shaped is bent or curved and the signal lines are not prone to be over etched on sides being bent or curved, the intruding path of the water vapor can be blocked. Therefore, the embodiment of the present disclosure can effectively reduce a probability of the water vapor entering the display area AA from gaps formed on the sides of the signal lines, thereby reducing a phenomenon of the display panel losing effectiveness or having poor display due to intrusion by the water vapor, and improving yields of the display panel.

Specifically, the signal lines 10 include the signal connecting section 101 and the signal main section 102 connected to each other. Wherein, the signal main section 102 is located in the bezel area BA, the end of the signal connecting section 101 is located in the bezel area BA and is connected to the signal main section 102, and the another end of the signal connecting section 101 extends to the terminal area CA and is connected to the flexible circuit board 20. The signal connecting section 101 and the signal main section 102 intersect at a default angle, the default angle is not limited, and the embodiment of the present disclosure takes the default angle being 90 degrees as an example for description. In the embodiment, the signal main section 102 and the signal connecting section 101 intersect at the default angle, so a probability of over-etching on sides of an intersection of the signal main section 102 and the signal connecting section 101 and then forming the gaps in processes can be reduced. Therefore, a probability of the water vapor entering the signal main section 102 can be reduced, and the yields of the display panel can be improved.

The signal main section 102 includes the first side a and the second side b opposite to each other, the signal main section 102 corresponding to the first side a is adjacent to the display area AA, and the signal main section 102 corresponding to the second side b is away from the display area AA. The signal connecting section 101 includes the third side c and the fourth side d that are opposite to each other, the third side c is connected to the first side a, and the fourth side d is connected to the second side b.

The signal connecting section 101 further includes a first segment positioned in the bezel area BA and a second segment positioned in the terminal area CA. Wherein, the first segment is connected to the signal main section 102, the second segment is connected to the first segment, and at least the first segment corresponding to the third side c is concavo-convex shaped. Since the signal main section 102 corresponding to the first side a is adjacent to the display area AA, both the first side a and the third side c are paths for the water vapor to intrude the display area. By setting at least the first segment corresponding to the third side c of the signal connecting section 101 to be concavo-convex shaped, the embodiment of the present disclosure, in one aspect, can extend the intruding path of the water vapor, and in another aspect, since undulations of the sides are bent or curved and the signal lines 10 are not prone to be over etched on the sides being bent or curved, the intruding path of the water vapor can be blocked. Therefore, the embodiment of the present disclosure can effectively reduce the probability of the water vapor entering the display area AA from the gaps formed on the sides of the signal lines, thereby reducing the phenomenon of the display panel losing effectiveness or having poor display due to intrusion by the water vapor, and improving the yields of the display panel.

In the embodiment of the present disclosure, a position in the signal connecting section 101 being concavo-convex shaped is provided with a plurality of convex parts 103 and a plurality of concave parts 104, and the convex parts 103 and the concave parts 104 are arranged alternatingly. Specifically, one concave part 104 is disposed between any two convex parts 103, and one convex part 103 is disposed between any two concave parts 104, thereby forming a side being concavo-convex shaped.

Shape outlines of the convex parts 103 and the concave parts 104 include polygonal or arc-shaped. It should be noted that a shape of each of the convex parts 103 may be same or different, a shape of each of the concave parts 104 may be same or different, and each of the convex parts 103 and the concave parts 104 may be independently polygonal or arc-shaped, and specifically may be triangular, rectangular, pentagonal, hexagonal, semi-circular, or semi-oval, which is not limited here.

The embodiment of the present disclosure takes the shapes of each of the convex parts 103 and each of the concave parts 104 being the same as an example for description.

In the embodiment of the present disclosure, the signal lines 10 include a first signal line 11 and a second signal line 12. Wherein, the signal main section 102 of the first signal line 11 is in the bezel area BA and on a lower side of the display area AA, that is, the signal main section 102 of the first signal line 11 is between the display area AA and the terminal area CA. The signal main section 102 of the second signal line 12 is in the bezel area BA and continuously surrounds a right side, an upper side, and a left side of the display area AA.

Wherein, the signal connecting section 101 of the first signal line 11 is connected to the flexible circuit board 20, and the signal main section 102 of the first signal line 11 is connected to the in-plane wirings, thereby transmitting the electrical signals to the transistor devices in the display area AA. The signal connecting section 101 of the second signal line 12 is connected to the flexible circuit board 20, and the signal main section 102 of the second signal line 12 is connected to the electrode components, thereby transmitting the electrical signals to the electrode components. Optionally, the electrode components may be a surface cathode, and the organic light-emitting functional layer includes anodes connected to the transistor devices. That is, the first signal line 11 transmits the electrical signals to the anodes of the organic light-emitting functional layer, and the second signal line 12 transmits the electrical signals to a cathode of the organic light-emitting functional layer, thereby realizing light-emitting functions of the organic light-emitting functional layer.

In the embodiment of the present disclosure, referring to FIGS. 2 and 3, the first signal line 11 includes a first signal connecting section 1011, the second signal line 12 includes a second signal connecting section 1012, and a position in the first signal connecting section 1011 corresponding to a third side c thereof is disposed opposite to a position in the second signal connecting section 1012 corresponding to a third side c thereof. That is, the position in the first signal connecting section 1011 being concavo-convex shaped is disposed opposite to the position in the second signal connecting section 1012 being concavo-convex shaped. Wherein, the convex parts 103 on the first signal connecting section 1011 are disposed corresponding to the concave parts 104 on the second signal connecting section 1012 by one to one, and the shapes of the convex parts 103 on the first signal connecting section 1011 match the shapes of the concave parts 104 on the second signal connecting section 1012. Therefore, the first signal line 11 and the second signal line 12 are allowed to be closer to each other, and the convex parts 103 on the first signal connecting section 1011 correspond to the concave parts 104 on the second signal connecting section 1012 and can fit with each other, which can reduce a distance between the first signal line 11 and the second signal line 12 as much as possible, thereby reducing a space in the terminal area CA.

Optionally, the convex parts 103 on the first signal connecting section 1011 may also be disposed corresponding to the convex parts 103 on the second signal connecting section 1012 by one to one.

In an embodiment of the present disclosure, referring to FIG. 3, the display panel includes the signal lines 10, and a part of the signal lines 10 is positioned in the terminal area CA, and another part thereof is positioned in the bezel area BA. Wherein, the signal lines 10 include the signal main section 102 disposed in the bezel area BA and the signal connecting section 101 having the end connected to the signal main section 102 and the another end extending to the terminal area CA.

The signal main section 102 includes the first side a and the second side b that are opposite to each other, and the signal connecting section 101 includes the third side c and the fourth side d that are opposite to each other.

The third side c is connected to the first side a, the first side a of the signal main section 102 faces the display area AA, and the third side c of the signal connecting section 101 is concavo-convex shaped, that is, all positions of the signal connecting section 101 corresponding to the third side c are concavo-convex shaped.

Specifically, the position in the signal connecting section 101 being concavo-convex shaped is provided with the plurality of convex parts 103 and the plurality of concave parts 104. Wherein, the shapes of each of the convex parts 103 and each of the concave parts 104 are all triangular, and a direction of sharp corners of the convex parts 103 is opposite to a direction of sharp corners of the concave parts 104, thereby forming a side being jagged shaped.

Wherein, the position in the first signal connecting section 1011 corresponding to the third side c and the position in the second signal connecting section 1012 corresponding to the third side c are formed with the plurality of convex parts 103 and the plurality of concave parts 104 arranged alternatingly, and the direction of the sharp corners of the convex parts 103 is opposite to the direction of the sharp corners of the concave parts 104, thereby forming the side being jagged shaped. Further, the position in the first signal connecting section 1011 being concavo-convex shaped is disposed opposite to the position in the second signal connecting section 1012 being concavo-convex shaped. The convex parts 103 on the first signal connecting section 1011 corresponding to the third side c are disposed corresponding to the concave parts 104 on the second signal connecting section 1012 corresponding to the third side c by one to one, and the shapes of the convex parts 103 on the first signal connecting section 1011 corresponding to the third side c match the shapes of the concave parts 104 on the second signal connecting section 1012 corresponding to the third side c.

Therefore, the embodiment of the present disclosure can reduce a probability of over-etching on the sides of the signal lines 10 and can extend a path for the water vapor to enter the display area AA from the gaps formed on the sides of the signal lines 10. Therefore, the present disclosure can effectively reduce the probability of the water vapor entering the display area AA from the gaps formed on the sides of the signal lines, thereby reducing the phenomenon of the display panel losing effectiveness or having poor display due to intrusion by the water vapor, and improving the yields of the display panel.

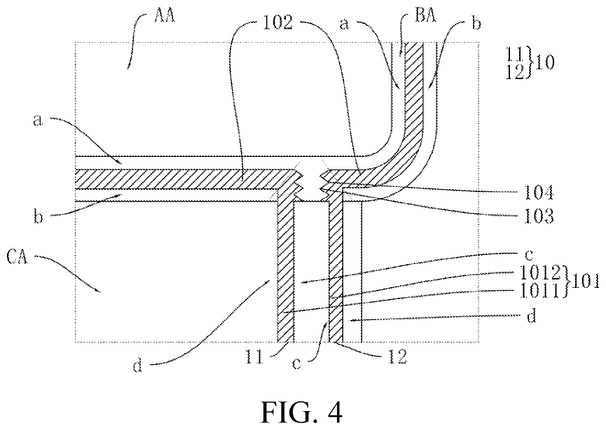

In another embodiment of the present disclosure, referring to FIG. 4, the display panel includes the signal lines 10, and the part of the signal lines 10 is positioned in the terminal area CA, and the another part thereof is positioned in the bezel area BA. Wherein, the signal lines 10 include the signal main section 102 disposed in the bezel area BA and the signal connecting section 101 having the end connected to the signal main section 102 and the another end extending to the terminal area CA.

In the embodiment of the present disclosure, the signal connecting section 101 includes the first segment positioned in the bezel area BA and the second segment positioned in the terminal area CA and connected to the first segment.

The signal main section 102 includes the first side a and the second side b that are opposite to each other, and the signal connecting section 101 includes the third side c and the fourth side d that are opposite to each other. The third side c is connected to the first side a, the signal main section 102 corresponding to the first side a is adjacent to the display area AA, and the first segment of the signal connecting section 101 corresponding to the third side c is concavo-convex shaped.

Specifically, a position in the first segment being concavo-convex shaped is provided with the plurality of convex parts 103 and the plurality of concave parts 104. Wherein, the shapes of each of the convex parts 103 and each of the concave parts 104 are all triangular, and the direction of the sharp corners of the convex parts 103 is opposite to the direction of the sharp corners of the concave parts 104, thereby forming the side being jagged shaped.

Wherein, the first segment of the first signal line 11 corresponding to the third side c and the first segment of the second signal line 12 corresponding to the third side c are both formed with the plurality of convex parts 103 and the plurality of concave parts 104 arranged alternatingly, and the direction of the sharp corners of the convex parts 103 is opposite to the direction of the sharp corners of the concave parts 104, thereby forming the side being jagged shaped.

Therefore, the embodiment of the present disclosure can reduce the probability of over-etching on the sides of the signal lines 10 and can extend the path for the water vapor to enter the display area AA from the gaps formed on the sides of the signal lines 10. Therefore, the present disclosure can effectively reduce the probability of the water vapor entering the display area AA from the gaps formed on the sides of the signal lines, thereby reducing the phenomenon of the display panel losing effectiveness or having poor display due to intrusion by the water vapor, and improving the yields of the display panel.

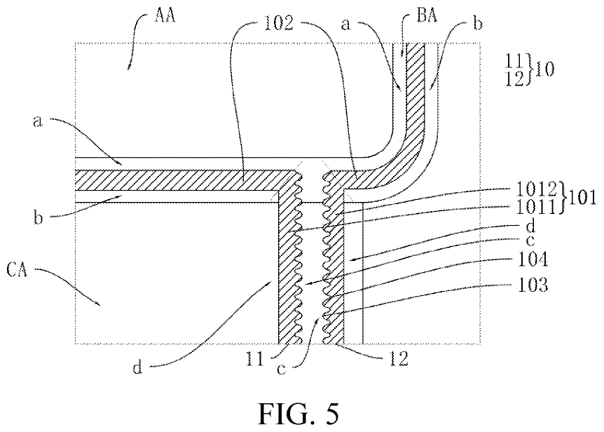

In another embodiment of the present disclosure, referring to FIG. 5, the display panel includes the signal lines 10, and the part of the signal lines 10 is positioned in the terminal area CA, and the another part thereof is positioned in the bezel area BA. Wherein, the signal lines 10 include the signal main section 102 disposed in the bezel area BA and the signal connecting section 101 having the end connected to the signal main section 102 and the another end extending to the terminal area CA.

The signal main section 102 includes the first side a and the second side b that are opposite to each other, and the signal connecting section 101 includes the third side c and the fourth side d that are opposite to each other. The third side c is connected to the first side a, the signal main section 102 corresponding to the first side a is adjacent to the display area AA, and the signal connecting section 101 corresponding to the third side c is concavo-convex shaped.

Specifically, the position in the signal connecting section 101 being concavo-convex shaped is provided with the plurality of convex parts 103 and the plurality of concave parts 104. Wherein, the shape outlines of each of the convex parts 103 and each of the concave parts 104 are all arc-shaped, that is, the shapes of the convex parts 103 and concave parts 104 are semi-circular, and a protruding direction of the convex parts 103 is opposite to a depression direction of the concave parts 104, thereby forming a side being wavy shaped.

Wherein, the position in the first signal connecting section 1011 corresponding to the third side c and the position in the second signal connecting section 1012 corresponding to the third side c are all formed with the plurality of convex parts 103 and the plurality of concave parts 104 arranged alternatingly, and the protruding direction of the convex parts 103 is opposite to the depression direction of the concave parts 104, thereby forming the side being wavy shaped. Further, the first signal connecting section 1011 corresponding to the third side c is disposed opposite to the second signal connecting section 1012 corresponding to the third side c, and the convex parts 103 on the first signal connecting section 1011 corresponding to the third side c are staggered from the concave parts 104 on the second signal connecting section 1012 corresponding to the third side c.

Therefore, the embodiment of the present disclosure can reduce the probability of over-etching on the sides of the signal lines 10 and can extend the path for the water vapor to enter the display area AA from the gaps formed on the sides of the signal lines 10. Therefore, the present disclosure can effectively reduce the probability of the water vapor entering the display area AA from the gaps formed on the sides of the signal lines, thereby reducing the phenomenon of the display panel losing effectiveness or having poor display due to intrusion by the water vapor, and improving the yields of the display panel.

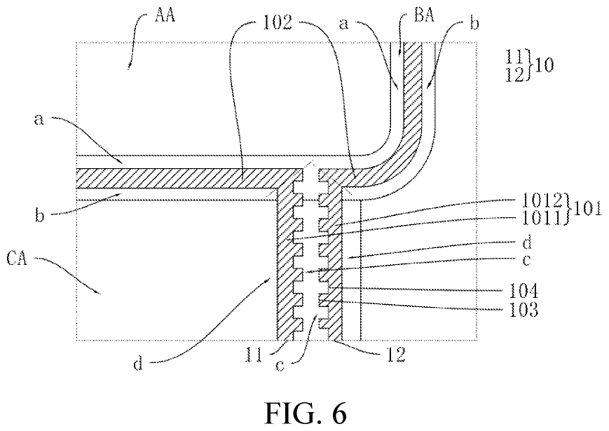

In another embodiment of the present disclosure, referring to FIG. 6, the display panel includes the signal lines 10, and the part of the signal lines 10 is positioned in the terminal area CA, and the another part thereof is positioned in the bezel area BA. Wherein, the signal lines 10 include the signal main section 102 disposed in the bezel area BA and the signal connecting section 101 having the end connected to the signal main section 102 and the another end extending to the terminal area CA.

The signal main section 102 includes the first side a and the second side b that are opposite to each other, and the signal connecting section 101 includes the third side c and the fourth side d that are opposite to each other. The third side c is connected to the first side a, the first side a of the signal main section 102 faces the display area AA, and the signal connecting section 101 corresponding to the third side c is concavo-convex shaped, that is, all positions of the signal connecting section 101 corresponding to the third side c are concavo-convex shaped.

Specifically, the position in the signal connecting section 101 being concavo-convex shaped is provided with the plurality of convex parts 103 and the plurality of concave parts 104. Wherein, the shapes of each of the convex parts 103 and each of the concave parts 104 are all rectangular, and a protruding direction of the convex parts 103 is opposite to a depression direction of the concave parts 104, thereby forming a side being gear shaped.

Wherein, the position in the first signal connecting section 1011 corresponding to the third side c and the position in the second signal connecting section 1012 corresponding to the third side c are formed with the plurality of convex parts 103 and the plurality of concave parts 104 arranged alternatingly, and the protruding direction of the convex parts 103 is opposite to the depression direction of the concave parts 104, thereby forming the side being gear shaped. Further, the first signal connecting section 1011 corresponding to the third side c is disposed opposite to the second signal connecting section 1012 corresponding to the third side c, and the convex parts 103 on the first signal connecting section 1011 corresponding to the third side c are staggered from the concave parts 104 on the second signal connecting section 1012 corresponding to the third side c.

Therefore, the embodiment of the present disclosure can reduce the probability of over-etching on the sides of the signal lines 10 and can extend the path for the water vapor to enter the display area AA from the gaps formed on the sides of the signal lines 10. Therefore, the present disclosure can effectively reduce the probability of the water vapor entering the display area AA from the gaps formed on the sides of the signal lines, thereby reducing the phenomenon of the display panel losing effectiveness or having poor display due to intrusion by the water vapor, and improving the yields of the display panel.

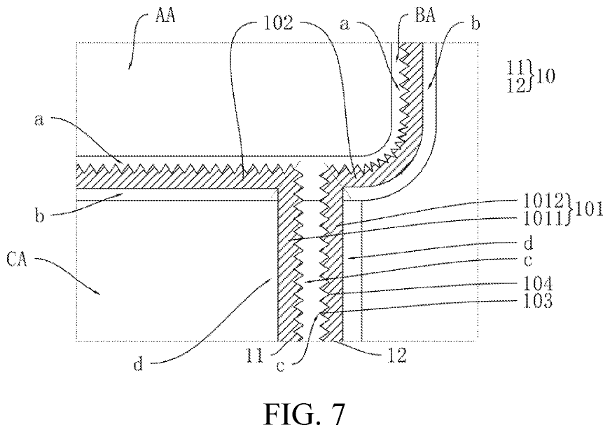

In another embodiment of the present disclosure, referring to FIG. 7, the display panel includes the signal lines 10, and the part of the signal lines 10 is positioned in the terminal area CA, and the another part thereof is positioned in the bezel area BA. Wherein, the signal lines 10 include the signal main section 102 disposed in the bezel area BA and the signal connecting section 101 having the end connected to the signal main section 102 and the another end extending to the terminal area CA.

The signal main section 102 includes the first side a and the second side b that are opposite to each other, and the signal connecting section 101 includes the third side c and the fourth side d that are opposite to each other. The third side c is connected to the first side a, the signal main section 102 corresponding to the first side a is adjacent to the display area AA, and the signal connecting section 101 corresponding to the third side c and the signal main section 102 corresponding to the first side a both are concavo-convex shaped. It should be noted that the drawing provided in this embodiment only shows a part of a structure as an example for description, and other sides being concavo-convex shaped are same as the part shown in FIG. 7.

Specifically, positions in the signal connecting section 101 and the signal main section 102 that are concavo-convex shaped are provided with the plurality of convex parts 103 and the plurality of concave parts 104. Wherein, the shapes of each of the convex parts 103 and each of the concave parts 104 are all triangular, and the protruding direction of the convex parts 103 is opposite to the depression direction of the concave parts 104, thereby forming the side being jagged shaped.

Wherein, the first signal line 11 corresponding to the first side a and the third side c and the second signal line 12 corresponding to the first side a and the third side c are formed with the plurality of convex parts 103 and the plurality of concave parts 104 arranged alternatingly, and the protruding direction of the convex parts 103 is opposite to the depression direction of the concave parts 104, thereby forming the side being jagged shaped.

Therefore, the embodiment of the present disclosure can reduce the probability of over-etching on the sides of the signal lines 10 and can extend the path for the water vapor to enter the display area AA from the gaps formed on the sides of the signal lines 10. Therefore, the present disclosure can effectively reduce the probability of the water vapor entering the display area AA from the gaps formed on the sides of the signal lines, thereby reducing the phenomenon of the display panel losing effectiveness or having poor display due to intrusion by the water vapor, and improving the yields of the display panel.

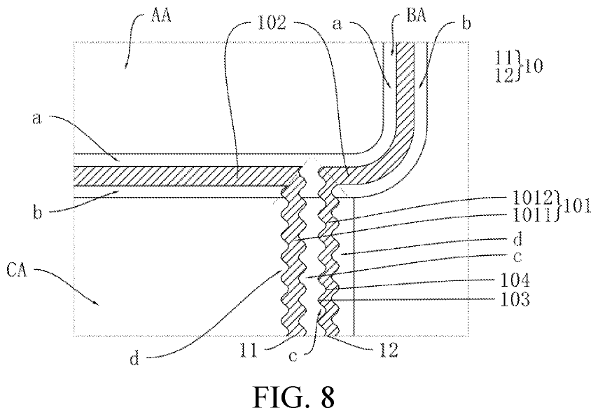

In another embodiment of the present disclosure, referring to FIG. 8, the display panel includes the signal lines 10, and the part of the signal lines 10 is positioned in the terminal area CA, and the another part thereof is positioned in the bezel area BA. Wherein, the signal lines 10 include the signal main section 102 disposed in the bezel area BA and the signal connecting section 101 having the end connected to the signal main section 102 and the another end extending to the terminal area CA.

The signal main section 102 includes the first side a and the second side b that are opposite to each other, and the signal connecting section 101 includes the third side c and the fourth side d that are opposite to each other. The third side c is connected to the first side a, the signal main section 102 corresponding to the first side a is adjacent to the display area AA, and the signal connecting section 101 corresponding to the third side c and the signal connecting section 101 corresponding to the fourth side d both are concavo-convex shaped.

Specifically, the position in the signal connecting section 101 being concavo-convex shaped is provided with the plurality of convex parts 103 and the plurality of concave parts 104. Wherein, for the third side c or the fourth side d, that is, for a same side, the shape outlines of each of the convex parts 103 and each of the concave parts 104 are arc-shaped, and the protruding direction of the convex parts 103 is opposite to the depression direction of the concave parts 104, thereby forming the side being wavy shaped.

In this embodiment, the convex parts 103 on the signal connecting section 101 corresponding to the third side c are disposed corresponding to the concave parts 104 on the signal connecting section 101 corresponding to the fourth sided by one to one, thereby allowing the signal connecting section 101 of the signal lines 10 to be wavy line shaped.

Wherein, both the first signal connecting section 1011 and the second signal connecting section 1012 are wavy line shaped.

Therefore, the embodiment of the present disclosure can reduce the probability of over-etching on the sides of the signal lines 10 and can extend the path for the water vapor to enter the display area AA from the gaps formed on the sides of the signal lines 10. Therefore, the present disclosure can effectively reduce the probability of the water vapor entering the display area AA from the gaps formed on the sides of the signal lines, thereby reducing the phenomenon of the display panel losing effectiveness or having poor display due to intrusion by the water vapor, and improving the yields of the display panel. In addition, in the display panel provided in this embodiment, the signal connecting section 101 of the signal lines 10 is wavy line shaped, and wavy line shaped signal lines 10 have a better anti-bending ability, so when the terminal area CA is bent, this embodiment can reduce a risk of breaking the signal lines

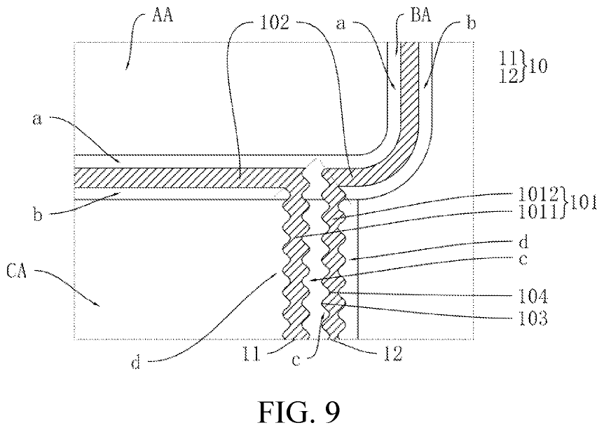

In another embodiment of the present disclosure, referring to FIG. 9, the display panel includes the signal lines 10, and the part of the signal lines 10 is positioned in the terminal area CA, and the another part thereof is positioned in the bezel area BA. Wherein, the signal lines 10 include the signal main section 102 disposed in the bezel area BA and the signal connecting section 101 having the end connected to the signal main section 102 and the another end extending to the terminal area CA.

The signal main section 102 includes the first side a and the second side b that are opposite to each other, and the signal connecting section 101 includes the third side c and the fourth side d that are opposite to each other. The third side c is connected to the first side a, the signal main section 102 corresponding to the first side a is adjacent to the display area AA, and the signal connecting section 101 corresponding to the third side c and the signal connecting section 101 corresponding to the fourth side d both are concavo-convex shaped.

Specifically, the position in the signal connecting section 101 being concavo-convex shaped is provided with the plurality of convex parts 103 and the plurality of concave parts 104. Wherein, for the third side c or the fourth side d, that is, for the same side, the shape outlines of each of the convex parts 103 and each of the concave parts 104 are arc-shaped, and the protruding direction of the convex parts 103 is opposite to the depression direction of the concave parts 104, thereby forming the side being wavy shaped.

In this embodiment, the convex parts 103 on the signal connecting section 101 corresponding to the third side c are staggered from the concave parts 104 on the signal connecting section 101 corresponding to the fourth side d, thereby allowing the signal connecting section 101 of the signal lines 10 to be wavy line shaped.

Wherein, both the first signal connecting section 1011 and the second signal connecting section 1012 are wavy line shaped.

Therefore, the embodiment of the present disclosure can reduce the probability of over-etching on the sides of the signal lines 10 and can extend the path for the water vapor to enter the display area AA from the gaps formed on the sides of the signal lines 10. Therefore, the present disclosure can effectively reduce the probability of the water vapor entering the display area AA from the gaps formed on the sides of the signal lines, thereby reducing the phenomenon of the display panel losing effectiveness or having poor display due to intrusion by the water vapor, and improving the yields of the display panel. In addition, in the display panel provided in this embodiment, the signal connecting section 101 of the signal lines 10 is wavy line shaped, and the wavy line shaped signal lines 10 have the better anti-bending ability, so when the terminal area CA is bent, this embodiment can reduce the risk of breaking the signal lines 10.

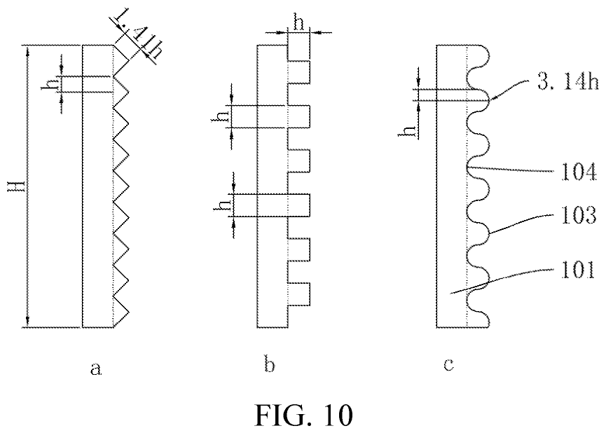

Further, referring to FIG. 10, the third side c of the signal connecting section 101 is taken as an example for description. Wherein, a structure of a is that: the convex parts 103 and the concave parts 104 on the signal connecting section 101 are isosceles right triangles. Wherein, a length of the signal connecting section 101 is H, a base length of the isosceles right triangles is 2h, and a waist length thereof is 2^{0.5}h, that is, 1.41h, thereby the intruding path of the water vapor on the signal connecting section 101 corresponding to the third side c can be extended to 1.41H.

Wherein, a structure of b is that: the convex parts 103 and the concave parts 104 on the signal connecting section 101 are squares. Wherein, the length of the signal connecting section 101 is H, a side length of the squares is h, and a perimeter of the convex parts 103 and the concave parts 104 is 2h, thereby the intruding path of the water vapor on the signal connecting section 101 corresponding to the third side c can be extended to 2H.

Wherein, a structure of c is that: the convex parts 103 and the concave parts 104 on the signal connecting section 101 are semi-circles. Wherein, the length of the signal connecting section 101 is H, a radius of the semi-circles is h, and the perimeter of the convex parts 103 and the concave parts 104 is πh, that is, 3.14h, thereby the intruding path of the water vapor on the signal connecting section 101 corresponding to the third side c can be extended to 3.14H.

In summary, the signal lines 10 provided in the embodiments of the present disclosure include the signal main section 102 disposed in the bezel area BA and the signal connecting section 101 having the end connected to the signal main section 102 and the another end extending to the terminal area CA. The signal main section 102 includes the first side a and the second side b that are opposite to each other, and the signal connecting section 101 includes the third side c and the fourth side d that are opposite to each other. The third side c is connected to the first side a, the signal main section 102 corresponding to the first side a is adjacent to the display area AA, and at least the first segment of the signal connecting section 101 that is in the bezel area BA corresponding to the third side c is concavo-convex shaped. That is, by disposing the sides being concavo-convex shaped on a path from the signal connecting section 101 to the display area AA, the present disclosure, in one aspect, can extend the intruding path of the water vapor, and in another aspect, since the undulations of the sides are bent or curved and the signal lines 10 are not prone to be over etched on the sides being bent or curved, the intruding path of the water vapor can be blocked. Therefore, the embodiments of the present disclosure can effectively reduce the probability of the water vapor entering the display area AA from the gaps formed on the sides of the signal lines, thereby reducing the phenomenon of the display panel losing effectiveness or having poor display due to intrusion by the water vapor, and improving the yields of the display panel.

In addition, an embodiment of the present disclosure further provides a display device, which includes the display panel mentioned in the above embodiments, a structure thereof is same as that in the above embodiments, and is not repeated here.

In the above embodiments, the description of each embodiment has its own emphasis. For a part that is not described in detail in an embodiment, refer to the related descriptions of other embodiments.

The display panel and the display device provided by the present disclosure are described in detail above. The specific examples are applied in the description to explain the principle and implementation of the disclosure. The description of the above embodiments is only for helping to understand the technical solution of the present disclosure and its core ideas, and it is understood that many changes and modifications to the described embodiment can be carried out without departing from the scope and the spirit of the disclosure that is intended to be limited only by the appended claims.

What is claimed is:

1. A display panel, comprising a display area, a bezel area adjacent to the display area, and a terminal area disposed on one side of the bezel area away from the display area;
wherein the display panel further comprises signal lines, and the signal lines comprise a signal main section disposed in the bezel area and a signal connecting section having one end connected to the signal main section in the bezel area and another end extending to the terminal area;
the signal main section comprises a first side and a second side opposite to the first side, and the signal main section corresponding to the first side is adjacent to the display area; and
the signal connecting section comprises a third side and a fourth side opposite to the third side, the third side is connected to the first side, and at least a part of the signal connecting section corresponding to the third side is concavo-convex shaped.

2. The display panel according to claim 1, wherein the signal connecting section comprises a first segment positioned in the bezel area and connected to the signal main section, and the first segment corresponding to the third side is concavo-convex shaped.

3. The display panel according to claim 2, wherein the signal connecting section further comprises a second segment positioned in the terminal area and connected to the first segment, and the second segment corresponding to the third side is concavo-convex shaped.

4. The display panel according to claim 1, wherein a position in the signal connecting section being concavo-convex shaped is provided with a plurality of convex parts and a plurality of concave parts arranged alternatingly, and shape outlines of the convex parts and the concave parts are independently polygonal or arc-shaped.

5. The display panel according to claim 4, wherein the signal lines comprise a first signal line and a second signal line, the first signal line comprises a first signal connecting section, the second signal line comprises a second signal connecting section, and a position in the first signal connecting section being concavo-convex shaped is disposed opposite to a position in the second signal connecting section being concavo-convex shaped; and wherein the convex parts on the first signal connecting section are disposed corresponding to the concave parts on the second signal connecting section by one to one, and shapes of the convex parts on the first signal connecting section match shapes of the concave parts on the second signal connecting section.

6. The display panel according to claim 4, wherein the signal connecting section corresponding to the fourth side is concavo-convex shaped.

7. The display panel according to claim 6, wherein the convex parts of the signal connecting section corresponding to the third side are staggered from the concave parts of the signal connecting section corresponding to the fourth side.

8. The display panel according to claim 6, wherein the convex parts of the signal connecting section corresponding to the third side correspond to the concave parts of the signal connecting section corresponding to the fourth side by one to one.

9. The display panel according to claim 1, wherein the signal main section corresponding to the first side is concavo-convex shaped. A display device, comprising a display panel, wherein the display panel comprises a display area, a bezel area adjacent to the display area, and a terminal area disposed on one side of the bezel area away from the display area;
the display panel further comprises signal lines, and the signal lines comprise a signal main section disposed in the bezel area and a signal connecting section having one end connected to the signal main section in the bezel area and another end extending to the terminal area;
the signal main section comprises a first side and a second side opposite to the first side, and the signal main section corresponding to the first side is adjacent to the display area; and
the signal connecting section comprises a third side and a fourth side opposite to the third side, the third side is connected to the first side, and at least a part of the signal connecting section corresponding to the third side is concavo-convex shaped.

11. The display device according to claim 10, wherein the signal connecting section comprises a first segment positioned in the bezel area and connected to the signal main section, and the first segment corresponding to the third side is concavo-convex shaped.

12. The display device according to claim 11, wherein the signal connecting section further comprises a second segment positioned in the terminal area and connected to the first segment, and the second segment corresponding to the third side is concavo-convex shaped.

13. The display device according to claim 10, wherein a position in the signal connecting section being concavo-convex shaped is provided with a plurality of convex parts and a plurality of concave parts arranged alternatingly, and shape outlines of the convex parts and the concave parts are independently polygonal or arc-shaped.

14. The display device according to claim 13, wherein the signal lines comprise a first signal line and a second signal line, the first signal line comprises a first signal connecting section, the second signal line comprises a second signal connecting section, and a position in the first signal connecting section being concavo-convex shaped is disposed opposite to a position in the second signal connecting section being concavo-convex shaped; and wherein the convex parts on the first signal connecting section are disposed corresponding to the concave parts on the second signal connecting section by one to one, and shapes of the convex parts on the first signal connecting section match shapes of the concave parts on the second signal connecting section.

15. The display device according to claim 13, wherein the signal connecting section corresponding to the fourth side is concavo-convex shaped.

16. The display device according to claim 15, wherein the convex parts of the signal connecting section corresponding to the third side are staggered from the concave parts of the signal connecting section corresponding to the fourth side.

17. The display device according to claim 15, wherein the convex parts of the signal connecting section corresponding to the third side correspond to the concave parts of the signal connecting section corresponding to the fourth side by one to one.

18. The display device according to claim 10, wherein the signal main section corresponding to the first side is concavo-convex shaped.
